(19) United States
(12) Patent Application Publication
(10) Pub. No.: US 2015/0179640 A1
(43) Pub. Date: Jun. 25, 2015

(54) COMMON FABRICATION OF DIFFERENT SEMICONDUCTOR DEVICES WITH DIFFERENT THRESHOLD VOLTAGES

(71) Applicant: GLOBALFOUNDRIES Inc., Grand Cayman (KY)

(72) Inventors: Hoon Kim, Clifton Park, NY (US); Kisik Choi, Hopewell Junction, NY (US); Jae Young Lee, Hopewell Junction, NY (US)

(21) Appl. No.: 14/134,358

(22) Filed: Dec. 19, 2013

(51) Int. Cl. H01L 27/088; H01L 21/28; H01L 21/265; H01L 21/223; H01L 21/8234; H01L 29/51

(52) U.S. Cl. CPC H01L 27/088; H01L 21/823412; H01L 29/517; H01L 21/265; H01L 21/2236; H01L 21/28158; H01L 21/823462

(57) ABSTRACT

A multi-device semiconductor structure including a p-type logic device, a p-type memory device, a n-type logic device and a n-type memory device are provided on a bulk silicon substrate. Each of these devices includes a dielectric layer and either a n-type or a p-type work function layer disposed over the dielectric layer. Some of the various device types of the multi-device semiconductor structure are protected, and impurities, such as aluminum and/or nitrogen, are added to the exposed work function layers to achieve one or more other desired work functions with different threshold voltages.

### BACKGROUND OF THE INVENTION

1. Technical Field

The present invention generally relates to semiconductor devices and methods of fabricating the semiconductor devices, more particularly, to providing different threshold voltages for different semiconductor devices being fabricated together.

2. Background Information

As is known, semiconductor devices, such as integrated circuit devices typically include a large number of transistors, logic devices and other types of devices within a single chip or wafer area. Each of these several different devices may have different corresponding threshold voltages (i.e., operating voltage or turn-on voltage) within the single chip or wafer area, to optimize performance or power. For example, an integrated circuit device may include a low threshold voltage device and a high threshold voltage device. Each of these different devices with different corresponding threshold voltages may be achieved either by doping the channel area using dopants such as, for example, boron or phosphorus or by halo implantation optimization.

However, the traditional techniques typically employed to manipulate the threshold voltage in such devices, result in non-uniform distribution of the resultant threshold voltages as well as using separate masks for each desired threshold voltage. While the non-uniformity of the resultant threshold voltages can cause mobility degradation and junction leakage current, using a separate mask for each desired threshold voltage may be cost prohibitive, more particularly so, as the semiconductor device fabrication processing continues to decrease to smaller dimensions.

Hence there exists a need to develop a method to provide different threshold voltages for different semiconductor devices fabricated together.

### SUMMARY OF THE INVENTION

The shortcomings of the prior art are overcome and additional advantages are provided through the provision, in one aspect, of a method of providing different threshold voltages for different semiconductor devices fabricated together. The method includes providing a semiconductor structure, the semiconductor structure including a semiconductor substrate and at least two different semiconductor devices coupled thererto, the at least two devices having at least two different threshold voltages, the structure further including a dielectric layer over the at least two semiconductor devices. The method further includes choosing at least one work function material that provides, has impurities added to provide, or can be combined with at least one other work function material to provide different work functions for the at least two semiconductor devices to achieve the different threshold voltages, a number of the at least one work function material including less than a number of the at least two different semiconductor devices, providing a blanket layer of one of the at least one work function material over the semiconductor structure, protecting one or more of the at least two different semiconductor devices and adding one or more impurities to the work function material over one or more unprotected semiconductor devices to achieve at least one other desired work function.

In accordance with another aspect, a combination semiconductor device is provided. The device includes a semiconductor substrate, at least one n-type semiconductor device coupled to the substrate, at least one p-type semiconductor device coupled to the substrate, and a blanket layer of a dielectric material over the semiconductor devices. The combination semiconductor device further includes at least one layer of at least one work function material over the blanket layer above each device type, a total number of work function materials for the combination semiconductor device including half a total number of individual semiconductor device types for the combination semiconductor device, and at least one layer of the at least one work function material over at least one of the semiconductor devices includes impurities.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional elevational view of one example of a multi-device semiconductor structure in fabrication, the multi-device semiconductor structure including different semiconductor devices requiring different threshold voltages, in accordance with one or more aspects of the present invention.

FIG. 2 depicts one example of the structure of FIG. 1 with a protective layer over one or more first semiconductor devices of n-type or p-type, in accordance with one or more aspects of the present invention.

FIG. 3 depicts one example of the structure of FIG. 2 after partial etching of a work function material over one or more second semiconductor devices of the opposite type without the protective layer, in accordance with one or more aspects of the present invention.

FIG. 4 depicts one example of the structure of FIG. 3 with a blanket conformal n-type work function material over the structure, in accordance with one or more aspects of the present invention.

FIG. 5 depicts one example of the structure of FIG. 4 after selective removal of the n-type work function material over one of the first semiconductor devices, in accordance with one or more aspects of the present invention.

FIG. 6 depicts one example of the structure of FIG. 5 after selectively partially exposing the n-type work function material over one of the second semiconductor devices, in accordance with one or more aspects of the present invention.

FIG. 7 depicts one example of selective partial doping of the exposed work function material in the structure of FIG. 6, in accordance with one or more aspects of the present invention.

FIG. 8 depicts one example of a resultant structure of FIG. 7 after different threshold voltages having been provided for different semiconductor devices, in accordance with one or more aspects of the present invention.

FIG. 9 depicts one example of an alternate structure of FIG. 1 with a protective layer having been partially removed to expose one of the first semiconductor devices, in accordance with one or more aspects of the present invention.

FIG. 10 depicts one example of the structure of FIG. 9, after selectively doping the partially exposed first semiconductor device, in accordance with one or more aspects of the present invention.

FIG. 11 depicts one example of the structure of FIG. 10 after selectively removing work function material over the second semiconductor devices, in accordance with one or more aspects of the present invention.

FIG. 12 depicts one example of the structure of FIG. 11 after conformal deposition of a n-type work function material, in accordance with one or more aspects of the present invention.

FIG. 13 depicts one example of the structure of FIG. 12 with a partial protective layer having been provided to partially expose one of the second semiconductor devices, in accordance with one or more aspects of the present invention.

FIG. 14 depicts one example of the structure of FIG. 13 after selectively doping the partially exposed second semiconductor device, in accordance with one or more aspects of the present invention.

FIG. 15 depicts one example of a resultant structure of FIG. 14 after different threshold voltages having been provided for different semiconductor devices, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

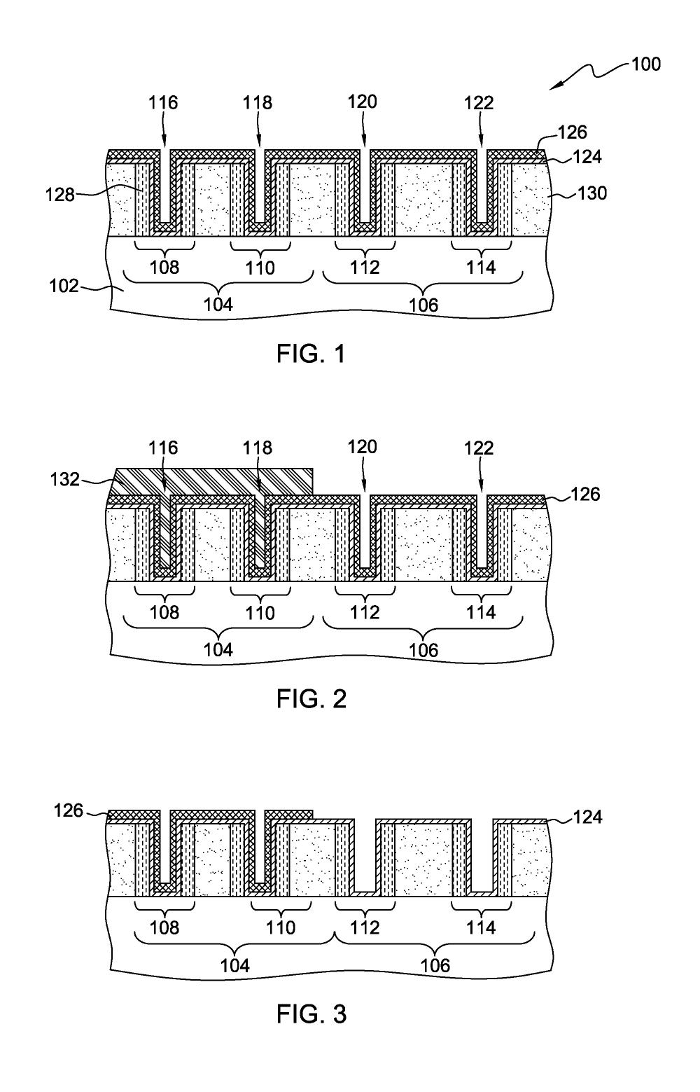

FIG. 1 is a cross-sectional view of one example of a multi-device semiconductor structure, generally denoted by 100, obtained at an intermediate stage of semiconductor fabrication of transistors. At the stage of fabrication depicted in FIG. 1, the multi-device semiconductor structure 100 includes a substrate 102, such as a bulk semiconductor material, for example, a bulk silicon wafer. In one example, substrate 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

Continuing with FIG. 1, multi-device semiconductor structure 100 includes at least two different semiconductor devices, for instance, one or more p-type semiconductor devices 104 and one or more n-type semiconductor devices 106 formed over substrate 102. In a specific example, p-type semiconductor devices 104 may include p-type logic device 108 and p-type memory device 110, while n-type semiconductor devices 106 may include n-type logic device 112 and n-type memory device 114. The p-type semiconductor devices 104 and n-type semiconductor devices 106 may include corresponding adjacent gate structures. By way of example, p-type semiconductor devices 104 may include gate structure 116 associated with p-type logic device 108 and gate structure 118 associated with p-type memory device 110, while n-type semiconductor devices 106 may include gate structure 120 associated with n-type logic device 112 and gate structure 122 associated with n-type memory device 114. As one example, each gate structure 116, 118, 120 and 122 may include one or more conformally-deposited layers, such as gate dielectric layer 124 and/or first work function layer 126 disposed over gate dielectric layer 124. Note that these layers may be formed using a variety of different materials and techniques, such as, for example, atomic layer deposition (ALD), metal organic chemical vapor deposition (MOCVD) and chemical vapor deposition (CVD). The thickness of the layers may also vary, depending upon the particular application.

As one example, gate dielectric layer 124 may be formed of a material such as silicon dioxide or a high-k dielectric material with a dielectric constant k greater than about 3.9 (note that k=3.9 for SiO₂), and may be deposited by performing a suitable deposition process, such as atomic layer deposition (ALD), chemical vapor deposition (CVD), physical vapor deposition (PVD), or the like. In one example, the thickness of gate dielectric layer 124 may be in the range of about 17 Angstroms to about 18 Angstroms. Examples of high-k dielectric materials that could be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate. As noted, first work-function layer 126 may be conformally deposited over gate dielectric layer 124, for example, via a deposition process such as ALD, MOCVD, CVD or PVD. By way of example, the work-function layers may include, for instance, one or more p-type metals or one or more n-type metals, depending on whether the gate structure is part of, for instance, a p-type semiconductor device or a n-type semiconductor device. As one skilled in the art will understand, each of the p-type semiconductor devices 104 and the n-type semiconductor devices 106 may include work function layers with different threshold voltages.

In the present example, first work-function layer 126 includes p-type work function material, which may be conformally deposited over gate dielectric layer 124. As used herein, a “p-type work function material” is a material that operates a p-type threshold voltage shift. In one example, p-type work function material may include titanium or high vacuum work function metals and their nitride/carbide such as, for example, titanium nitride (TiN), tantalum nitride (TaN), titanium aluminum nitride (TiAlN), tantalum aluminum nitride (TaAlN), niobium nitride (NbN), vanadium nitride (VN), tungsten nitride (WN). In another example, first work function layer 126 may include an appropriate refractory metal carbide, for example, titanium carbide (TiC), titanium aluminum carbide (TiAlC), titanium aluminide (TiAl) tantalum carbide (TaC), tantalum aluminum carbide (TaAlC), niobium carbide (NbC), vanadium carbide (VC), etc. In another example, first work function layer 126 may also include ruthenium (Ru), platinum (Pt), molybdenum (Mo), cobalt (Co) and alloys and combinations thereof. The thickness of first work-function layer 126 may be, for example, in the range of about 1 nanometer to about 30 nanometers. In a specific example, the thickness of first work-function layer 126 may be about 35 Angstroms (3.5 nm).

Alternatively, first work function layer 126 may include n-type work function material, which may be conformally deposited over gate dielectric layer 124. As used herein, an “n-type work function material” is a material that operates a n-type threshold voltage shift. In such an example, first work function layer 126 may include, but is not limited to, titanium aluminide (TiAl), tantalum aluminum carbide (TaAlC), zirconium aluminide (ZrAl), tungsten aluminide (WAl), tantalum aluminide (TaAl), hafnium aluminide (HfAl). The thickness of the n-type work function material, which may be conformally deposited using, for example, ALD, MOCVD, CVD or PVD, may be in the range of about 2 nanometers to about 30 nanometers, and preferably about 30 Angstroms (3 nm) to about 50 Angstroms (5 nm).

Referring still to FIG. 1, although not critical to the invention, sidewall spacers 128 are provided along the sidewalls of the corresponding gate structures. Sidewall spacers 128 may be deposited using conventional deposition processes, such as, for example, chemical vapor deposition (CVD), low-pressure CVD, or plasma-enhanced CVD (PE-CVD). In one example, sidewall spacers 128 may have a conventional thickness and may include or be fabricated of a material such as, for example, silicon nitride. In a specific example, silicon nitride may be deposited using process gases such as, for example, dichlorosilane (SiH₂Cl₂) and ammonia (NH₃) and using known process conditions. In another example, silicon nitride may also or alternatively be deposited using halogen-free precursor such as, for example, bis(t-butylamino)silane (BTBAS) (SiC₈N₂H₂₂) and ammonia (NH₃) at about 550° C.

Continuing further with FIG. 1, an interlayer 130 is shown disposed over entire substrate 102 including adjacent gate structures 116, 118, 120 and 122 of corresponding p-type devices 104 and n-type devices 106. In one example, interlayer 130 may include, but is not limited to, any silicon-containing materials such as silicon oxide. As another example, where the substrate comprises silicon, the interlayer could be silicon dioxide doped with nitrogen, carbon, or a metal, such as lanthanum, aluminum, erbium, germanium or the like. The interlayer may be formed by, for example, oxidation of silicon using O₃, SC1 wet (chemical oxide process using ammonia (NH₃), hydrogen peroxide (H₂O₂) and deionized water), or oxidation at high temperature. Alternatively, the interlayer could be formed using thermal oxide growth, or using deposition processes, including, but not limited to, chemical vapor deposition (CVD) and plasma enhanced CVD (PECVD).

A protective layer 132 is partially provided over structure 100; in this case, over gate structures 116 and 118 of corresponding p-type logic device 108 and p-type memory device 110, as depicted in FIG. 2. Although not shown in the figures, one skilled in art will know that the partial protective layer may be achieved by blanket deposition of the protective material over the entire multi-device structure, for instance, over first work function layer 126, e.g., the p-type work function layer, disposed within gate structures 116 and 118 of p-type semiconductor devices 104 as well as gate structures 120 and 122 of corresponding n-type logic device 112 and n-type memory device 114. As understood, the protective layer may then be patterned, using one or more lithographic processing steps, to be selectively removed from over n-type semiconductor devices 106, exposing n-type logic device 112 and n-type memory device 114, respectively, for subsequent fabrication. The protective layer may be deposited using a variety of techniques, such as, for example, chemical vapor deposition (CVD), atomic layer deposition (ALD) or physical vapor deposition (PVD) processes, and the thickness of the layer above the gate structures may be (in one example) sufficient to allow for subsequent planarization of the structure. By way of example, protective layer 132 may be or include an organic material. For instance, flowable oxide such as, for example, a hydrogen silsesquioxane polymer, or a carbon-free silsesquioxane polymer, may be deposited as the protective material 132 by flowable chemical vapor deposition (F-CVD). In another example, protective material 132 may be or include an organic polymer, for example, polyacrylate resin, epoxy resin, phenol resin, polyamide resin, polyimide resin, unsaturated polyester resin, polyphenylene ether resin, polyphenylenesulfide resin or benzocyclobutene (BCB). In another example, protective material 132 may be or include any conventional organic planarizing layer (OPL) material or any conventional bottom anti-reflective coating (BARC) material or any conventional photoresist (PR) material.

As illustrated in FIG. 3, exposed work function layer 126 (see FIG. 2) disposed over n-type semiconductor devices 106, for instance, n-type logic device 112 and n-type memory device 114, is selectively removed. This selective removal process may be performed, for example, using a conventional isotropic wet etching process or a conventional dry etching process. In one example, SC1 wet etch (using ammonia, hydrogen peroxide and deionized water) may be performed at room temperature, selective on n-type work-function metal to a p-type work-function metal (e.g., TiN). Note that this selective removal process advantageously results in exposing gate dielectric layer 124 disposed over n-type logic device 112 and n-type memory device 114, while preventing exposure of work function layer 126 disposed over p-type semiconductor devices 104. A non-selective chemical-mechanical polish or an etch-back polish may then be employed to remove protective layer 132 (see FIG. 2) from over gate structures 116 and 118 of corresponding p-type logic device 108 and p-type memory device 110, thereby exposing work function layer 126 disposed over p-type semiconductor devices 104.

Note that in an alternate example, in the case of first work function layer 126 being a n-type work function material, exposed work function layer 126 (FIG. 2) need not be removed. However, the work function of such an “n-type work function material” may be altered by adding impurities, e.g., by implanting with a dopant, to create a work function layer giving a desired threshold voltage, using subsequently described processes.

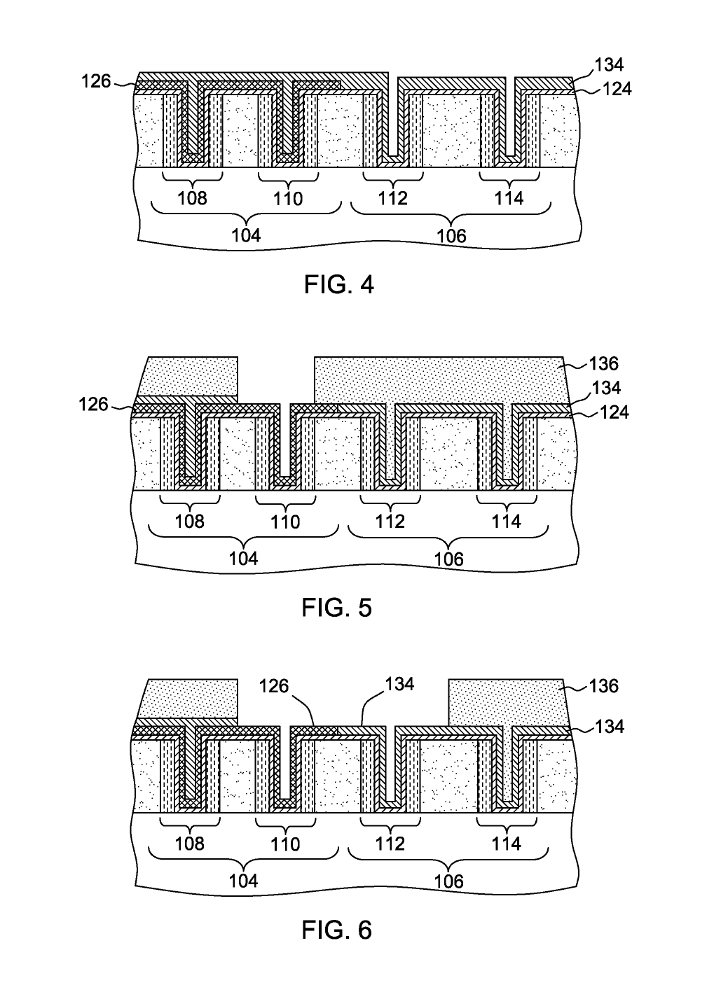

As depicted in FIG. 4, a second work function layer 134 is conformally deposited over the entire multi-device semiconductor structure of FIG. 3. By way of example, second work-function layer 134 may include or be fabricated of work function material that is substantially different from the first work function layer 126. In one example, second work function layer 134 may include a n-type work function material, which may be conformally deposited, for example, using chemical vapor deposition (CVD), atomic layer deposition (ALD), sputtering or platting. As used herein, “n-type work function layer” may include a material that operates a n-type threshold voltage shift. In one example, second work function layer 134 may include, but is not limited to, titanium aluminide (TiAl), zirconium aluminide (ZrAl), tungsten aluminide (WAl), tantalum aluminide (TaAl), hafnium aluminide (HfAl), titanium aluminum carbide (TiAlC). The thickness of second work function layer 134 may be in the range of about 3 nanometers to about 30 nanometers. Note that by the addition of work function layer 134, the threshold voltages (Vₜ) of p-type semiconductor devices 104 are substantially altered from the threshold voltages (Vₜ) of n-type semiconductor devices 106.

As illustrated in FIG. 5, a protective layer 136 may be conformally provided over second work function layer 134, disposed over p-type logic device 108 and n-type semiconductor devices 106. As discussed above, the protective layer may be deposited using a variety of techniques, such as, for example, chemical vapor deposition (CVD), atomic layer deposition (ALD) or physical vapor deposition (PVD) processes, and the thickness of the layer above the gate structures may be (in one example) sufficient to allow for subsequent planarization of the structure. By way of example, protective layer 136 may be or include an organic material. For instance, flowable oxide such as, for example, a hydrogen silsesquioxane polymer, or a carbon-free silsesquioxane polymer, may be deposited as the protective material 136 by flowable chemical vapor deposition (F-CVD). In another example, protective material 136 may be or include an organic polymer, for example, polyacrylate resin, epoxy resin, phenol resin, polyamide resin, polyimide resin, unsaturated polyester resin, polyphenylene ether resin, polyphenylenesulfide resin or benzocyclobutene (BCB). In another example, protective material 136 may be fabricated or include any conventional organic planarizing layer (OPL) material or any conventional bottom anti-reflective coating (BARC) material or any conventional photoresist (PR) material.

Continuing further with FIG. 5, one or more lithographic processing steps may be performed to selectively pattern a portion of sacrificial protective layer 136 from over p-type memory device 110. Although not depicted in the figures, one skilled in art will understand that the lithographic processing steps may typically include (for instance) providing an anti-reflective coating layer over the protective mask and providing a patterned photoresist layer over the anti-reflective layer. The patterning process may proceed through the layers to transfer the pattern from the patterned photoresist layer to etch through sacrificial protective layer 136. These lithographic processing steps advantageously facilitate in selectively exposing second work function layer 134 disposed over p-type memory device 110, while preventing exposure of second work function layer 134 over p-type logic device 108, as well as over n-type logic device 112 and n-type memory device 114.

The exposed second work function layer 134 is then selectively removed from over p-type memory device 110, to expose the underlying first work function layer 126. This selective removal of second work function layer 134 may be performed using one or more conventional etching processes such as, for example, isotropic wet etching processes or anisotropic dry etching processes. In a specific example, the second work function layer 134 may be selectively removed using wet chemistries such as, for example, sulfuric peroxide mixture (SPM), dilute ammonium hydroxide: hydrogen peroxide mixture or hydrogen peroxide. Note that this selective removal process advantageously proceeds without affecting the second work function layer 134 disposed over the other devices, due to the remaining protective layer 136.

As illustrated in FIG. 6, one or more additional lithographic processing steps may be performed to selectively pattern protective layer 136 to remove a portion from over n-type logic device 112. Although not depicted in the figures, one skilled in art will understand that the lithographic processing steps may typically include (for instance) providing an anti-reflective coating layer over the protective mask and providing a patterned photoresist layer over the anti-reflective layer. The patterning process may proceed through the layers to transfer the pattern from the patterned photoresist layer to etch through sacrificial protective layer 136. These lithographic processing steps advantageously facilitate in selectively exposing second work function layer 134 disposed over n-type logic device 112, along with selectively exposing first work function layer 126 disposed over p-type memory device 110, while preventing exposure of second work function layer 134 over p-type logic device 108 and n-type memory device 114. This selective removal of protective layer 136 and selective exposure of the work function layers advantageously facilitates in providing different threshold voltages for different devices.

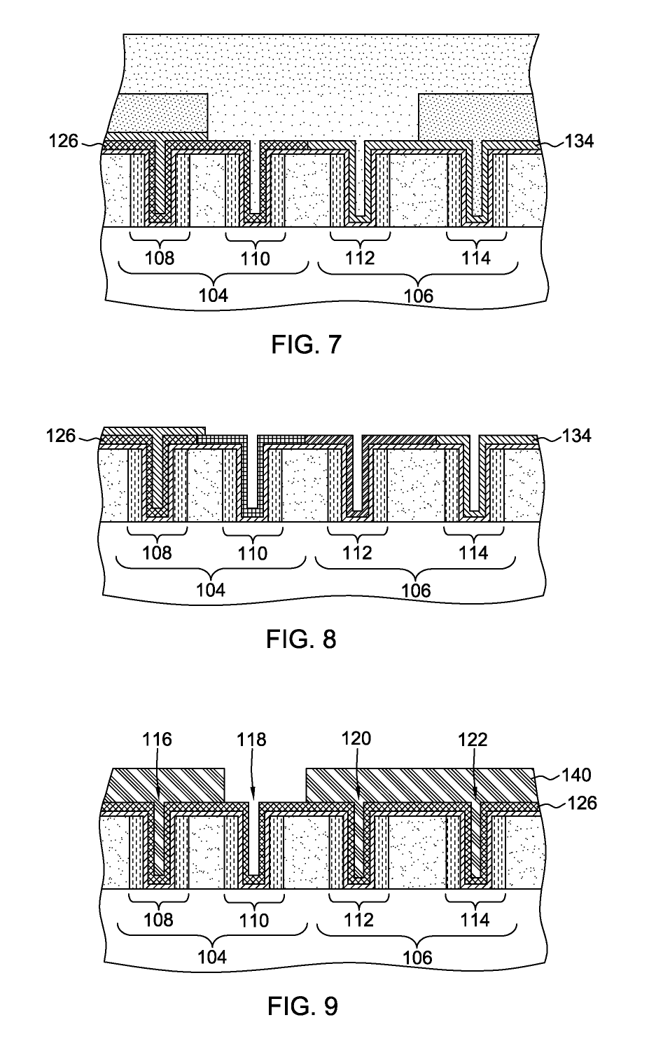

As illustrated in FIG. 7, the threshold voltages between different logic devices and memory devices may be tuned to desirable values by causing impurities to be added to the exposed work function layers, for example, by implanting the exposed work function layers of different devices with a same dopant, to tailor the work function to achieve a desired threshold voltage for a desired device. In one example, the doping process employed may be a plasma doping process or, as another example, an ion implantation process. At the time of filing, a plasma doping process is preferred, as it provides a conformal distribution of dopant within a work function layer. The dopant employed may be a p-type dopant or a n-type dopant. Note that as used herein, p-type dopant refers the addition of an impurity to the work function layer to increase the work function of the work function material (e.g., metal). Examples of a p-type dopant may include nitrogen (N), carbon (C), Fluorine (F), and oxygen. The n-type dopant refers to the addition of impurities to, for example, the work function layer, which contribute to decrease the work function of the work function material, for example, aluminum, titanium, tantalum, hafnium, potassium, calcium, sodium, or lanthanum. Alternatively, a material with inherently low work function could be chosen, eliminating the need for n-type doping.

Note that the dopant used to implant the work function layers are substantially similar. In one example, exposed first work function layer 126, of p-type memory device 110 and exposed second work function layer 134 of n-type logic device 112 are selectively implanted with a dopant by performing a plasma doping process or an ion implantation process. In a specific example, exposed p-type work function layer 126 of p-type memory device 110 and exposed n-type work function layer 134 of n-type logic device 112 are implanted with aluminum, a p-type dopant. This implantation of the exposed work function layers advantageously facilitates in decreasing the work function of the exposed layers, due to the work function effect of the dopant used, and thereby decreasing the threshold voltages of p-type memory device 110 and n-type logic device 112. In another specific example, exposed p-type work function layer 126 of p-type memory device 110 and exposed n-type work function layer 134 of n-type logic device 112 are implanted with nitrogen, a n-type dopant. This implantation of the exposed work function layers advantageously facilitates in increasing the work function of the exposed layers, due to the work function effect of the dopant used, for example, the n-type dopant, and thereby increasing the threshold voltages of p-type memory device 110 and n-type logic device 112. Note that during the selective doping process, the threshold voltages of p-type logic device 108 and n-type memory device 114 remains unaffected, due to protective layer 136 remaining thereover.

Note that, as discussed above, in an alternate example, in the case of first work function layer 126 (see FIG. 1) being an “n-type work function material,” exposed work function layer 126 (see FIG. 2) may be implanted with a dopant by performing a plasma doping process, such as, for example, nitrogen plasma or ion implantation, to alter the work function of the exposed layer, resulting in a desired threshold voltage. In a specific example, exposed n-type work function layer 126 (see FIG. 2) may be implanted with nitrogen plasma. In such an example, the work function of the exposed n-type work function layer 126 (see FIG. 2), such as, for example, titanium aluminum carbide, may be altered to a p-type work function material, such as titanium aluminum nitride.

FIG. 8 depicts the resultant structure of FIG. 7, after plasma doping or ion implantation has been performed to tune the threshold voltages of different devices by selectively implanting with a dopant to achieve desirable values. Note that the doping process performed as discussed in connection with FIG. 7, advantageously results in providing a different threshold voltage for each individual semiconductor device within the same multi-device semiconductor structure. By way of example, as discussed above, the doping process results in p-type semiconductor devices 104, including p-type logic device 108 having a threshold voltage of about 4.95 eV and p-type memory device 110 having a threshold voltage of about 4.8 eV, while n-type logic device 112 has a threshold voltage of about 4.25 eV to about 4.3 eV and n-type memory device 110 has a threshold voltage of about 4.1 eV to about 4.2 eV, respectively. In this example, the p-type devices had a base work function metal of TiN, while the n-type devices had a base work function metal of TiC. The n-type logic device and p-type memory device were doped with aluminum to lower their work functions (i.e., lower their Vₜ) for nFET Vt, or increase Vt for pFET, as compared to their corresponding type device that remained undoped.

Alternatively, the threshold voltages between different logic devices and different memory devices may be tuned to desirable values by implanting the exposed work function layers of different devices from the example above with a substantially different dopant, to create a work function with individual threshold voltages for a desired logic device or a desired memory device, for example. Such an implementation may be achieved by a process described below, which begins with the structure of FIG. 1.

Accordingly, as depicted in FIG. 9, a protective layer 140 may be blanketly provided over the multi-device semiconductor structure, for instance, over first work function layer 126, and patterned, using one or more lithographic processing steps, to selectively expose first work function layer 126 disposed over p-type memory device 110, for subsequent fabrication. Protective layer 140 may be deposited using a variety of techniques, such as, for example, chemical vapor deposition (CVD), atomic layer deposition (ALD) or physical vapor deposition (PVD) processes, and the thickness of the layer above the gate structures may be (in one example) sufficient to allow for subsequent planarization of the structure. By way of example, protective layer 140 may be or include an organic material. For instance, flowable oxide such as, for example, a hydrogen silsesquioxane polymer, or a carbon-free silsesquioxane polymer, may be deposited as the protective material 140 by flowable chemical vapor deposition (F-CVD). In another example, protective material 140 may be or include an organic polymer, for example, polyacrylate resin, epoxy resin, phenol resin, polyamide resin, polyimide resin, unsaturated polyester resin, polyphenylene ether resin, polyphenylenesulfide resin or benzocyclobutene (BCB). In another example, protective material 140 may be or include any conventional organic planarizing layer (OPL) material or any conventional bottom anti-reflective coating (BARC) material or any conventional photoresist (PR) material.

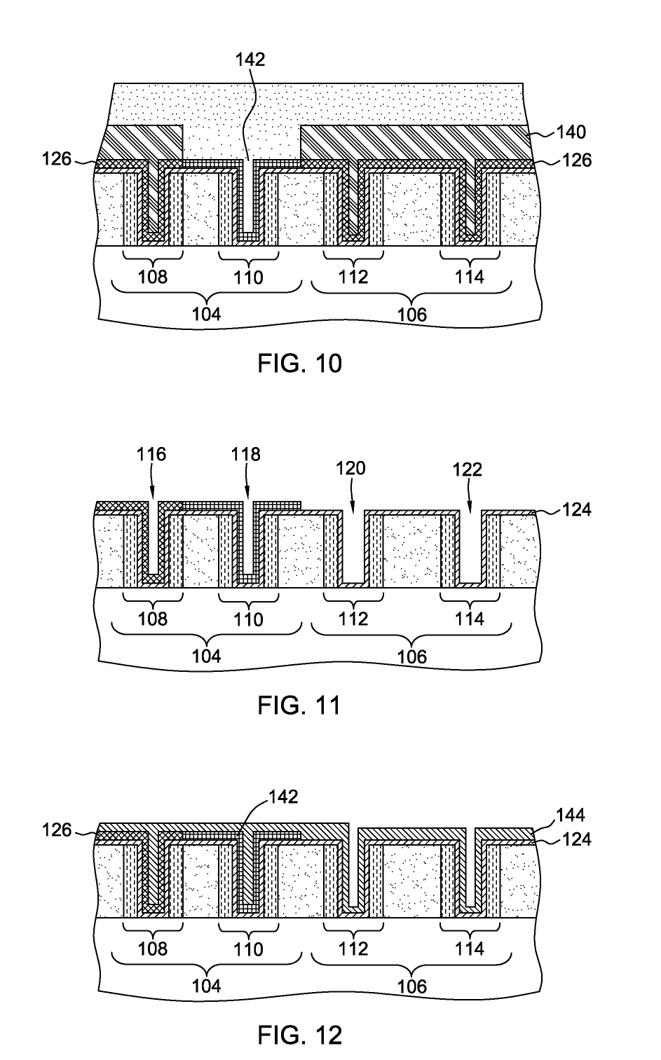

As illustrated in FIG. 10, the threshold voltage of the exposed first work function layer 126 (see FIG. 9) disposed over p-type memory device 110 may be selectively altered by implanting with a dopant, to create a work function layer 142 with a desired threshold voltage for the p-type memory device. Note that this doping process advantageously facilitates in creating work function layer 142 for p-type memory device 110 that results in a threshold voltage that is lower than the threshold voltage of work function layer 126 disposed over adjacent p-type logic device 108. As discussed above, a plasma doping process or ion implantation process may be employed, with the plasma doping process being preferred, to provide a conformal distribution of dopant within the work function layer. The dopant employed may be, for example, a p-type dopant. Note that as used herein, “p-type dopant” refers the addition of an impurity to the work function layer to create deficiencies of valence electrons. Examples of p-type dopant may include, but are not limited to, aluminum (Al), indium or titanium. Note also that this selective doping process proceeds without affecting the work function or resulting threshold voltage of first work function layer 126 disposed over n-type semiconductor devices 106.

A non-selective chemical-mechanical polish or an etch-back polish may then be employed, as depicted in FIG. 11, to remove protective layer 140 (see FIG. 9) from over gate structures 120 and 122 of corresponding n-type logic device 112 and n-type memory device 114, thereby exposing first work function layer 126 (see FIG. 9) disposed over n-type semiconductor devices 106. The exposed first work function layer 126 (see FIG. 9) may then be selectively removed from over n-type semiconductor devices 106. This selective removal process may be performed using a conventional isotropic wet etching process or a conventional dry etching process. For example, room temperature SC1 cleaning can be used to selectively remove TiN from above a high-k layer without damage to the devices below. Note that this selective removal process advantageously results in exposing gate dielectric layer 124 disposed over n-type logic device 112 and n-type memory device 114, while preventing exposure of first work function layer 126 disposed over p-type logic device 108 or work function layer 142 disposed over p-type memory device 110.

As depicted in FIG. 12, a second work function layer 144 is provided over the multi-device semiconductor structure of FIG. 11. Note that the second work function layer 144 is conformally deposited over exposed first work function layer 126 disposed over p-type logic device 108 and doped work function layer 142 of p-type memory device 110, as well as over gate dielectric layer 124 of n-type semiconductor devices 106. By way of example, second work-function layer 134 may include or be fabricated of work function material that is substantially different from the first work function layer 126 and modified work function layer 142. In one example, second work function layer 144 may include a n-type work function material, which may be conformally deposited, for example, using chemical vapor deposition (CVD), atomic layer deposition (ALD), sputtering or platting. In one example, second work function layer 144 may include, but is not limited to, titanium aluminide (TiAl), zirconium aluminide (ZrAl), tungsten aluminide (WAl), tantalum aluminide (TaAl), hafnium aluminide (HfAl), titanium aluminum carbide (TiAlC). The thickness of second work function layer 144 may be in the range of about 2 nanometers to about 30 nanometers. Note that the threshold voltages (Vₜ) of p-type semiconductor devices 104 are substantially different from the threshold voltages (Vₜ) of n-type semiconductor devices 106, due to the addition of second work function layer 144.

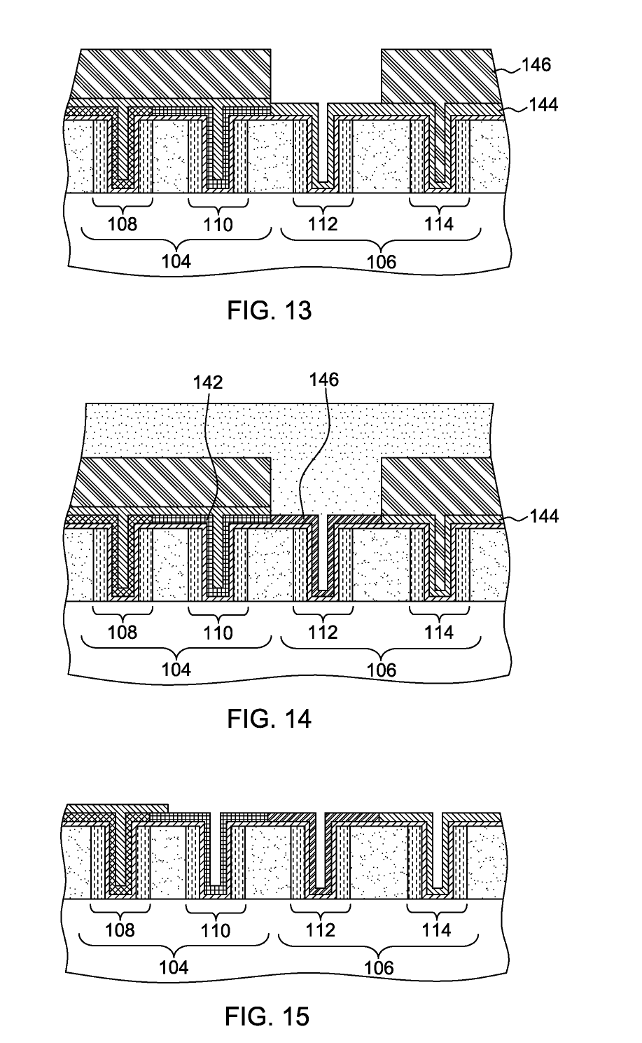

As illustrated in FIG. 13, a protective layer 146 may be conformally provided over second work function layer 144, disposed over p-type semiconductor devices 104 as well as over n-type semiconductor devices 106. As discussed above, the protective layer may be deposited using a variety of techniques, such as, for example, chemical vapor deposition (CVD), atomic layer deposition (ALD) or physical vapor deposition (PVD) processes, and the thickness thereof may be (in one example) sufficient to allow for subsequent planarization of the structure. By way of example, protective layer 146 may be or include an organic material. For instance, protective layer 146 may include a flowable oxide, such as, for example, a hydrogen silsesquioxane polymer, or a carbon-free silsesquioxane polymer, and may be deposited, for example, by flowable chemical vapor deposition (F-CVD). In another example, protective material 146 may be or include an organic polymer, for example, polyacrylate resin, epoxy resin, phenol resin, polyamide resin, polyimide resin, unsaturated polyester resin, polyphenylene ether resin, polyphenylenesulfide resin or benzocyclobutene (BCB). In another example, protective material 146 may be fabricated or include any conventional organic planarizing layer (OPL) material, any conventional bottom anti-reflective coating (BARC) material or any conventional photoresist (PR) material.

Continuing further with FIG. 13, one or more lithographic processing steps may be performed to pattern protective layer 146 to selectively remove a portion thereof from over n-type memory device 112. Although not depicted in the figures, one skilled in art will understand that the lithographic processing steps may typically include (for instance), providing an anti-reflective coating layer over the protective layer and providing a patterned photoresist layer over the anti-reflective layer. The patterning process may proceed through the layers to transfer the pattern from the patterned photoresist layer to etch through protective layer 146. These lithographic processing steps advantageously facilitate in selectively exposing second work function layer 144 disposed over n-type memory device 112, while preventing exposure of second work function layer 144 over p-type semiconductor devices 104 and over n-type logic device 114.

As illustrated in FIG. 14, the threshold voltage of n-type memory device 112 may be selectively altered by implanting work function layer 144 (see FIG. 13) thereover with a dopant, to create a work function layer 146 with a desired threshold voltage for the n-type memory device. Note that this doping process advantageously facilitates in creating work function layer 146 for a n-type memory device, with a threshold voltage that is higher than the threshold voltage of second work function layer 144 disposed over adjacent n-type logic device 114. As discussed above, a plasma doping process or ion implantation process may be used, with the plasma doping process being preferred, to provide a conformal distribution of dopant within the work function layer. The dopant employed may be, for example, a n-type dopant. Note that as used herein, “n-type dopant” refers to the addition of impurities to, for example, the work function layer, which contribute more electrons and may include, for example, nitrogen (N) and carbon (C). Note also that this selective doping process proceeds without affecting the work function or resulting threshold voltage of the work function layers disposed over p-type semiconductor devices 104.

FIG. 15 depicts the resultant structure of FIG. 14, after plasma doping or ion implantation has been performed to tune the threshold voltages of the exposed work function layers of different devices by implanting with different dopants to achieve desirable work function values. Note that the doping process performed as discussed in connection with FIG. 14, advantageously results in providing a different threshold voltage for each individual semiconductor device within the same multi-device semiconductor structure. By way of example, as discussed above, the doping process results in p-type logic device 108 having a threshold voltage of about −200 mV to about −300 mV and p-type memory device 110 having a threshold voltage of about −300 mV to about −400 mV, while n-type logic device 112 has a threshold voltage of about 200 mV to about 300 mV and n-type memory device 110 has a threshold voltage of about 300 mV to about 400 mV.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a semiconductor structure, the structure comprising a semiconductor substrate and at least two different semiconductor devices coupled thereto, the at least two devices having at least two different threshold voltages, the structure further comprising a dielectric layer over the at least two semiconductor devices;
choosing at least one work function material that provides, has impurities added to provide or can be combined with at least one other work function material to provide different work functions for the at least two semiconductor devices to achieve the different threshold voltages, wherein a number of the at least one work function material comprises less than a number of the at least two semiconductor devices;
providing a blanket layer of one of the at least one work function material over the semiconductor structure;
protecting one or more of the at least two semiconductor devices; and
adding one or more impurities to the work function material over one or more unprotected semiconductor devices to achieve at least one other desired work function.

2. The method of claim 1, wherein the at least two semiconductor devices comprise at least one n-type semiconductor device and at least one p-type semiconductor device.

3. The method of claim 2, wherein the at least two semiconductor devices comprise one n-type semiconductor device and one p-type semiconductor device, wherein the blanket layer of the one of the at least one work function material comprises a n-type work function material, and wherein adding one or more impurities comprises transforming the n-type work function material into a p-type work function material.

4. The method of claim 3, wherein the n-type work function material comprises one of titanium aluminide and titanium aluminum carbide, and wherein the transformed work function material comprises titanium aluminum nitride.

5. The method of claim 2, wherein adding one or more impurities comprises doping, wherein the at least one n-type semiconductor device comprises at least one n-type logic device and at least one n-type memory device, and wherein the at least one p-type semiconductor device comprises at least one p-type logic device and at least one p-type memory device.

6. The method of claim 5, wherein the doping is performed once.

7. The method of claim 5, wherein the doping is performed once for the n-type semiconductor devices and once for the p-type semiconductor devices.

8. The method of claim 1, wherein adding one or more impurities comprises at least one of plasma doping and ion implantation.

9. The method of claim 1, wherein the at least two different semiconductor devices comprises more than two different semiconductor devices, the method further comprising:
providing a second blanket layer of a different one of the at least one work function material;
protecting one or more other of the more than two different semiconductor devices; and
doping the work function material over at least one unprotected semiconductor device to achieve at least one other desired work function.

10. The method of claim 9, further comprising, after providing the second blanket layer, removing the different one of the at least one work function material over one or more of the more than two different semiconductor devices.

11. The method of claim 1, wherein the protecting comprises blanketly providing and patterning a protective layer over the one of at least one work function material.

12. The method of claim 1, further comprising removing at least one of the at least one work function material above at least one of the at least two different semiconductor devices.

13. A semiconductor device, comprising:
a semiconductor substrate;
at least one n-type semiconductor device coupled to the substrate;
at least one p-type semiconductor device coupled to the substrate;
a blanket layer of a dielectric material over the semiconductor devices;
at least one layer of at least one work function material over the blanket layer above each device type, wherein a total number of work function materials for the combination semiconductor device comprises half a total number of individual semiconductor device types for the combination semiconductor device, and wherein at least one layer of the at least one work function material above at least one of the semiconductor devices comprises impurities.

14. The semiconductor device of claim 13, wherein the at least one n-type semiconductor device comprises a n-type transistor, wherein the at least one p-type semiconductor device comprises a p-type transistor, and wherein the work function material comprises a n-type work function material.

15. The semiconductor device of claim 14, wherein the n-type work function material comprises titanium and one or more of aluminum, nitrogen, oxygen and carbon.

16. The semiconductor device of claim 13, wherein the at least one n-type semiconductor device comprises two different n-type semiconductor devices, wherein the at least one p-type semiconductor device comprises two different p-type semiconductor devices, and wherein each semiconductor device has a different work function requirement.

17. The semiconductor device of claim 16, wherein the at least one work function material comprises a n-type work function material and a p-type work function material.

18. The semiconductor device of claim 17, wherein the n-type work function material comprises one or more of aluminum, titanium, tantalum, hathium, potassium, calcium, sodium, or lanthanum, and wherein the p-type work function material comprises one or more of nitrogen, carbon, fluorine and oxygen.

19. The semiconductor device of claim 13, wherein the dielectric material comprises a high-k dielectric material.
